(19) United States
(12) Patent Application Publication
(10) Pub. No.: US 2025/0264712 A1
(43) Pub. Date: Aug. 21, 2025

(54) ADAPTIVE MIRROR WITH MECHANICAL MEDIATOR LAYER AND MICROLITHOGRAPHIC PROJECTION EXPOSURE APPARATUS

(71) Applicant: Carl Zeiss SMT GmbH, Oberkochen (DE)

(72) Inventors: Erik LOOPSTRA, Ederheim Huernheim (DE); Andreas Raba, Niederschoenenfeld (DE)

(21) Appl. No.: 19/197,208

(22) Filed: May 2, 2025

Related U.S. Application Data
(63) Continuation of application No. PCT/EP2023/075654, filed on Sep. 18, 2023.

(30) Foreign Application Priority Data
Nov. 4, 2022 (DE) 10 2022 211 639.9

(51) Int. Cl. G02B 26/08; G02B 5/08; G03F 7/00

(52) U.S. Cl. CPC G02B 26/0825; G03F 7/70266; G03F 7/7085; G03F 7/70891; G03F 7/70958; G02B 5/0808; G02B 5/0891

(57) ABSTRACT

An adaptive mirror for a microlithographic projection exposure apparatus comprises: a mirror substrate; an optical effective surface; a reflective layer system for reflecting electromagnetic radiation incident on the optical effective surface; an actuator layer for producing a locally variable deformation of the optical effective surface; and a mediator layer between the actuator layer and the reflective layer system. The mediator layer comprises an elastic mechanical mediator layer. The elastic mechanical mediator layer can be 0.1 mm and 50 mm thick and can have a modulus of elasticity of between 10 GPa and 300 GPa. A microlithographic projection exposure apparatus comprises such an adaptive mirror.

### CROSS-REFERENCE TO RELATED APPLICATIONS

The present application is a continuation of, and claims benefit under 35 USC 120 to, international application No. PCT/EP2023/075654, filed Sep. 18, 2023, which claims benefit under 35 USC 119 of German Application No. 10 2022 211 639.9, filed Nov. 4, 2022. The entire disclosure of each of these applications is incorporated by reference herein.

### FIELD

The disclosure relates to an adaptive mirror for a microlithographic projection exposure apparatus, comprising a mirror substrate, an optical effective surface, a reflective layer system for reflecting electromagnetic radiation incident on the optical effective surface, an actuator layer for producing a locally variable deformation of the optical effective surface, and a mediator layer between the actuator layer and the reflective layer system.

### BACKGROUND

Projection exposure apparatuses are used for producing extremely fine structures, such as in semiconductor components or other microstructured component parts. A functional principle of the apparatuses is based on the production of extremely fine structures down to the nanometer range by way of generally reducing imaging of structures on a mask, a so-called reticle, on an element to be structured, a so-called wafer, that is provided with photosensitive material. In general, minimum dimensions of the structures produced are directly dependent on the wavelength of the light used. Typically, the light is shaped for the optimum illumination of the reticle in an illumination optical unit. Recently, light sources having an emission wavelength in the range of a few nanometers, for example between 1 nm and 120 nm, such as in the region of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, such as 193 nm. With the desire to be able to produce smaller and smaller structures, the desired properties with respect to optical correction in the systems have likewise increased further.

In projection lenses designed for the EUV range, e.g., at wavelengths of for example approximately 13 nm or approximately 7 nm, mirrors are used as optical components for the imaging process owing to the general lack of availability of suitable light-transmissive refractive materials.

Due to the absorption of the electromagnetic radiation (e.g. emitted by an EUV light source), the mirrors can heat up and can undergo an associated thermal expansion or deformation, which in turn can adversely affect the imaging properties of the optical system. Variations in gravity depending on the installation site or the geographic location of the system, for example, are another potential cause of aberrations occurring during operation of a projection exposure apparatus.

In order to at least partially compensate for the above-described problems and also generally to increase the image position accuracy and image quality (both along the optical axis, or in the light propagation direction, and also in the lateral direction, or perpendicular to the optical axis or light propagation direction), it is known to design one or more mirrors in the optical system as an adaptive mirror with an actuator layer—for example composed of a piezoelectric material, wherein an electric field of locally varying strength is generated across the piezoelectric layer by applying an electric voltage to electrodes arranged on both sides of the piezoelectric layer. In the case of a local deformation of the piezoelectric layer, the reflective layer system of the adaptive mirror also deforms, with the result that (possibly also temporally variable) imaging aberrations can be compensated for at least partially by appropriately controlling the electrodes. The deformation of the reflective layer system can also generally be used to further optimize the microlithographic imaging process.

Even if the above-described principal of an adaptive mirror makes it possible, to a certain degree, to carry out an efficient correction of aberrations in the course of the deformation or actuation of the mirror, in practice, for example if relatively large actuations or deformations are used, the desired expansion of the piezoelectric layer perpendicular to the optical effective surface of the mirror may also be accompanied by a lateral expansion (i.e. expansion taking place parallel to the optical effective surface) of the piezoelectric layer. Such a lateral expansion may likewise lead to a deformation of the mirror substrate or mirror, which may make it more difficult overall to achieve controlled setting for instance in order to attain a desired correction of aberrations.

DE 10 2016 201 445 A1 discloses an adaptive mirror for a microlithographic projection exposure apparatus, wherein a piezoelectric layer serves as a compensation layer. By applying a locally varying electric voltage, a locally varying deflection of the piezoelectric layer can be produced, which in turn can cause a deformation of the reflective layer system and thus a wavefront change for light incident on the optical effective surface and can be used for aberration correction. In that case, the locally varying deflection of the actuator layer can give rise to so-called top-hat profiles, i.e. edges formed marginally with respect to the deformation. The edges can result in an increase in the stray light and increased mechanical loading of the reflective layer system and thus of the adaptive mirror. By virtue of the moderately electrically conductive layer as disclosed in DE 10 2016 201 445 A1, a potential gradient between the electrodes can be attained, which can reduce the formation of edges upon the deformation of the reflective layer system. However, the electrical connection of the electrodes to one another significantly can increase the desired properties with respect to charge control and closed-loop control of the actuator.

Furthermore, a portion of the electromagnetic radiation can be absorbed by the reflective layer system, which is usually formed as a multilayer system, for example composed of molybdenum and silicon layers, and thus can lead to the heating of the mirror. An actuator layer which directly adjoins the reflective layer system or is situated in the vicinity thus may be maximally exposed to the temperatures occurring at the mirror and to the spatial and temporal temperature gradients. Due to the usually temperature-dependent behavior of the piezoelectric actuators, such as the parasitic thermal expansion, the temperature dependence of the actuator characteristic curve or temperature-induced aging of the actuator material, the performance of the optical system may be adversely affected.

### SUMMARY

The present disclosure seeks to provide an improved adaptive mirror and an improved projection exposure apparatus.

In an aspect, the disclosure provides an adaptive mirror, such as for a microlithographic projection exposure apparatus. The adaptive mirror comprises: a mirror substrate; an optical effective surface; a reflective layer system for reflecting electromagnetic radiation incident on the optical effective surface; an actuator layer for producing a locally variable deformation of the optical effective surface; and a mediator layer between the actuator layer and the reflective layer system. The mediator layer is formed as an elastic mechanical mediator layer, has thickness of between 0.1 mm and 50 mm, and has a modulus of elasticity of between 10 GPa and 300 GPa, preferably between 50 GPa and 150 GPa. The actuator layer is an electrostrictive or piezoelectric actuator layer arranged between a first electrode and a second electrode.

In another aspect, the disclosure provides a microlithographic projection exposure apparatus comprising an illumination device and a projection lens. An adaptive mirror according to the disclosure is present in the microlithographic projection exposure apparatus.

An adaptive mirror according to the disclosure includes a mediator layer that is an elastic mechanical mediator layer, which can have a thickness of between 0.1 mm and 50 mm, such as between 0.1 mm and 20 mm, for example between 0.1 mm and 10 mm, for example between 0.5 mm and 5 mm. The elastic mechanical mediator layer can have a modulus of elasticity of between 10 GPa and 300 GPa, such as between 50 GPa and 150 GPa, for example between 60 GPa and 80 GPa.

Dispensing with an electrical mediator layer can help enable control electrodes to be embodied in a manner electrically insulated from one another. This can help make it possible to greatly improve the describability of the system and to effectively minimize non-deterministic effects such as creep and hysteresis. The stray light problem can be minimized in a targeted manner by the now continuous and smooth progression of the deformation. The mechanical stresses within the actuator layer and high-frequency disturbances of the optical effective surface can be reduced or suppressed by the elastic mechanical mediator layer, which can act as a low-pass filter. The elastic mechanical mediator layer additionally can constitute a thermal mass, such that a change in the radiation power absorbed at the optical surface can lead to a reduced temporal temperature gradient in comparison with the optical surface and a reduced maximum temperature. Heat conduction in the elastic mechanical mediator layer also can result in a lateral heat distribution, such that the temperature profile might only have greatly reduced local temperature gradients.

The actuator layer can be arranged between the mirror substrate and the reflective layer system. It can be formed as a single-layer, two-layer or multilayer system. The multilayered design can help make it possible to increase the travel of the actuator layer and thus the deformation effect with the same individual ply thickness.

Furthermore, it can be desirable for the elastic mechanical mediator layer to be formed in a manner free of piezostrictive and/or magnetostrictive and/or electrostrictive material. For example, it can be desirable for the elastic mechanical mediator layer to be formed as an electrical nonconductor. Furthermore, it can be desirable for the elastic and mechanical mediator layer to be configured in such a way that it is nonconductively connected to a layer adjacent to it.

In an embodiment, the elastic mechanical mediator layer can also have an electrical insulation layer, in such a way that the elastic and mechanical mediator layer and the layer adjacent thereto (actuator layer) are electrically nonconductively connected via the insulation layer. In such an embodiment, the mechanical mediator layer itself can be electrically conductive.

For improving the closed-loop control, the fabrication and the thermal describability of the adaptive mirror, it can be desirable for the elastic mechanical mediator layer to be fabricated from the same material as the mirror substrate. This can help make it possible to minimize internal mechanical stresses owing to different thermal expansions. In this case, the mirror substrate material can be formed for example from fused silica or titanium silicate glass, such as from a titanium silicate glass which has a zero crossing temperature (ZCT), i.e. a coefficient of thermal expansion of zero or approximately zero, and is operated in the region of the zero crossing temperature.

In an embodiment, it is also possible for an electrical mediator layer to be present in addition to the elastic mechanical mediator layer. In this case, the electrical mediator layer can be formed for example as a piezoelectric layer. The combination of a mirror comprising a mechanical mediator layer and an additional electrical mediator layer can help enable the mechanical mediator layer to be made thinner.

The coefficient of thermal expansion of the elastic mechanical mediator layer can be <2 ppm per kelvin in order to help counteract an unwanted actuation of the actuator layer as a result of the heat input of the electromagnetic radiation incident on the optical effective surface.

The thermal conductivity of the elastic mechanical mediator layer in the direction of the surface normal of the optical effective surface can be less than 10 W/(m*K), such as less than 5 W/(m*K), for example less than 2 W/(m*K). Alternatively, the thermal conductivity parallel to the optical effective surface can be increased in order to dissipate the heat input as a result of the electromagnetic radiation toward the outside out of the mirror and to minimize temperature gradients parallel to the optical effective surface.

In order to further minimize parasitic disturbances resulting from heat input as a result of the electromagnetic radiation, it can be desirable for at least one cooling channel to be arranged within the elastic mechanical mediator layer. This at least one cooling duct, optionally a plurality of cooling ducts, can be fluidically connected to a cooling circuit. Alternatively or additionally, the mirror substrate can have at least one cooling channel that is fluidically connected to a cooling circuit.

Alternatively or additionally, it can be desirable for a temperature-regulating device to be present, which is arranged on or near the optical effective surface and/or is arranged on or near or within the actuator layer. The temperature-regulating device can be a spatially resolved temperature-regulating device and can be formed as a heating element, in particular as a heater or a radiant heater. Likewise, the actuator layer or an additional actuator layer can be formed as a temperature-regulating device by virtue of the fact that under suitable control it dissipates energy and thus can help bring about a local temperature increase. The combination of the cooling channels in the mirror substrate and/or in the actuator layer and the temperature-regulating device can help enable the thermally dictated parasitic disturbances to be reduced.

For better closed-loop control of the temperature and thus for improved describability of the system, it can be desirable for at least one temperature sensor to be present, and for the at least one temperature sensor to be arranged on or near or within the actuator layer or on or near the optical effective surface. In this case, the temperature sensor can be formed as a strain sensor or else the actuator layer itself can serve as a temperature sensor via its temperature-induced change in layer thickness, particularly if the actuator layer is formed as a piezoelectric layer. A plurality of temperature sensors can be provided, and can be localized in such a way that the temperature field within the actuator layer can be deduced.

The disclosure provides for the actuator layer to be formed as an electrostrictive actuator layer arranged between a first electrode and a second electrode. The actuator layer can be formed from electrostrictive polymers. In the case of electrostrictive materials, the geometry can be changed depending on an electric field present at the materials, the strain being proportional to the square of the field present locally in the crystal structure.

Alternatively, the disclosure provides for the actuator layer to be formed as a piezoelectric actuator layer arranged between a first electrode and a second electrode. In this case, the piezoelectric actuator layer can be formed from lead zirconate-lead titanate, for example. Alternatively, the actuator layer can also be formed from a magnetostrictive, photostrictive or electrostrictive material. In order to increase the adjustment travel of the actuator layer, a plurality of piezoelectric or magnetostrictive or photostrictive or electrostrictive actuator layers can be present, too, each of which is arranged between two electrodes. The second electrode layer can also be formed as a plurality of second electrodes, for example as a plurality of control electrodes. Likewise, the multilayered embodiment can help make it possible to attain the same travel with the same total thickness of the actuator layers by virtue of smaller electrical potential differences of the control electrode, on account of the smaller distance between the electrodes.

It can be desirable for the piezoelectric layer or the electrostrictive layer to be formed as a thin-film piezoelectric layer or thin-film electrostrictive layer, and for the thickness of the piezoelectric/electrostrictive layer to be for example between 0.1 μm and 1 mm, such as between 1 μm and 100 μm, for example between 1 μm and 10 μm. As an example, the piezoelectric layer/electrostrictive layer cam have a thickness of 3 μm to 7 μm. The small geometric extent in the thickness direction means that only small temperature gradients should be expected in the thickness direction, which can greatly simplify mechatronic modeling and thus can lead to a simpler and more robust and easily controllable adaptive mirror system. By virtue of the design of the actuator layer as a piezoelectric actuator layer and/or by virtue of a thin-film piezoelectric/electrostrictive layer, this can also function as a local electrical heating element and as a temperature sensor.

In the case of a thin-film piezo layer near the surface, a change in the geometry of the piezo layer in the z-direction can result in a local z-displacement of the reflective layer system and thus in the desired effect of local wavefront influencing. However, a local change in the geometry of the piezo layer in the x-direction and the y-direction of the piezo can also result in a deformation of the mirror, since in this case a local moment can be introduced into the mirror and can result in the mirror, primarily the main body of the mirror, being subjected to a deformation that is not greatly delimited locally. It has been demonstrated that in the case of a concept with a piezoelectric actuator and a mechanical mediator layer, the deformation profile can be significantly less dependent on the effect of the x-y strain of the piezo layer. Furthermore, it has been demonstrated that the deformation of the mechanical mediator layer at the optical effective surface can be significantly more than 80% by comparison with a concept without a mechanical mediator layer if the mechanical mediator layer has a thickness of approximately 5 mm.

Furthermore, it can be desirable for the mirror also to have an electrical mediator layer in addition to the mechanical mediator layer. In this case, the additional electrical mediator layer can be designed in such a way that a continuous progression of the electrical potential between the second electrodes (control electrodes) is realized. The electrical conductivity of the layer can be dimensioned such that the self-heating owing to the current flow between the second electrodes (control electrodes) is less than 5 K. Furthermore, the electrical mediator layer can be formed from a piezoelectric material, wherein the piezoactuator and the electrical mediator layer can be formed from the same or else different piezoelectric material. Moreover, the piezoactuator and the mediator layer formed from piezoelectric material can also have an electric field applied to them independently of one another.

In order to improve the performance of the adaptive mirror, it can be desirable for the ratio of the lateral electrode center-to-center distance to a thickness of the elastic mechanical mediator layer to be between 0.1 and 10, such as between 0.2 and 5, for example between 0.5 and 2.

The production of thin-film piezo layers of sufficient quality can be costly and complex. Moreover, piezoactuators can tend toward aging, i.e. toward reduction of the electromechanical coupling over time. This can pose a risk to the optical performance and service life of the adaptive mirror. Alternatively, it can be desirable for the actuator layer to be formed as a thermal actuator, with a deformation layer having a zero crossing-free coefficient of thermal expansion in an operating range between 20° C. and 60° C., and optionally between 20° C. and 40° C. In this case, the deformation layer can be configured to absorb electromagnetic radiation in the infrared wavelength range, whereby the deformation layer is heated by impingement of electromagnetic radiation in the infrared wavelength range. Alternatively, the thermal actuator can also additionally have at least one heating element which is at least thermally connected to the deformation layer. The temperature of the deformation layer can then be changed via the heating element in order to enable an at least regional layer thickness change and thus deformation. In this case, the thermal actuator can be formed alternately from heating element layers and deformation layers. The heating element can be formed as a conductor loop or as a piezoelectric layer, or from at least one resistor or from an electrically conductive material or as a coil or from ferromagnetic material or as a ferromagnetic, inductive layer.

Alternatively, the actuator layer can also be formed as a thermal actuator, with a deformation layer which has a coefficient of thermal expansion of approximately 0 at a zero crossing temperature, wherein a control unit is configured to operate the deformation layer at a temperature not equal to the zero crossing temperature in order to induce an at least regional layer thickness change of the deformation layer. By virtue of the thermal actuator being operated at a temperature not equal to the zero crossing temperature, the deformation layer can be operated in a range in which its coefficient of thermal expansion is not equal to zero, such that an expansion of the deformation layer is made possible. By way of example, the zero crossing temperature is in the range of between 5° and 15°, such that a deformation is already attained at room temperature. However, the deformation layer can have an arbitrary zero crossing temperature and can be operated in conjunction with an arbitrary temperature or temperature range deviating therefrom. In an embodiment of a relatively simple design, the deformation layer is configured to absorb electromagnetic radiation in the infrared wavelength range. This can help enable heating of the deformation layer and an attendant deformation as a result of impingement of electromagnetic radiation in the IR range.

In an embodiment, in addition to the deformation layer, the actuator layer can have at least one heating element which is at least thermally connected to the deformation layer and which is configured, via the control unit, to change, such as to heat, the deformation layer to a temperature not equal to the zero crossing temperature of the deformation layer, in order to induce an at least regional layer thickness change of the deformation layer. In this case, the deformation layer and the heating element can be combined in one layer.

The deformation layer can have a first region or a first layer, in which the coefficient of thermal expansion is zero or approximately zero at a first zero crossing temperature, and a second region or a second layer, in which the coefficient of thermal expansion is zero or approximately zero at a second zero crossing temperature different than the first zero crossing temperature. In other words, the deformation layer can have different regions or layers with mutually different zero crossing temperatures. In this case, it can be desirable for, in a region on or near the optical effective surface or the reflective layer system, the deformation layer to have a first zero crossing temperature corresponding approximately to the temperature range caused by the heating resulting from the electromagnetic radiation. By contrast, the deformation layer can have a second region or a second layer on or near the heating element, the second region or layer having a second zero crossing temperature different than the first zero crossing temperature. It is desirable for the temperature ranges of the first zero crossing temperature and the second zero crossing temperature to not overlap. A spatial separation between desired actuation effect and unwanted radiation-induced deformation effect can be attained as a result.

If a cooling facility is present in the mechanical mediator layer, then the spatial separation between actuation heating and the optical effective surface can be improved even further. The local setting of the zero crossing temperature and thus the coefficient of thermal expansion (CTE) distribution can be effected by raw material with different CTEs and different zero crossing temperatures being joined together during the fabrication of the adaptive mirror.

Joints used from a design standpoint or from a production engineering standpoint can be utilized particularly here. If the cooling channels are produced by the structuring of one or both component parts and subsequent joining, then this joint can form a desirable location for the interface of the two materials with different CTEs.

This can be effected at a place which has a joint owing to the dictates of design or owing to the dictates of production, such as in connection planes for the fluidic cooling or for mounting heating elements.

Furthermore, the deformation layer can be made relatively thin, i.e. its thickness is for example between 0.1 μm and 100 μm, such as between 0.5 μm and 20 μm, for example between 0.5 μm and 5 μm, and can be embodied with a material with a relatively high CTE, for example between 5*10⁻⁶ 1/K and 15*10⁻⁶ 1/K. In this case, it is possible to disregard the temperature gradient over the thickness of the layer in the modeling of the resultant deformation profile of the optical surface, which can result in a simpler and more robust system. The wavelength of the electromagnetic radiation can moreover be chosen in such a way that the power is absorbed in the deformation layer having a zero crossing-free coefficient of thermal expansion, while the mirror substrate is transparent to this wavelength. For this purpose, the deformation layer can additionally comprise one or more absorption elements. Likewise, the heat input into the reflective layer system and into the deformation layer can be influenced by beam shaping.

The deformation layer can be embodied in a structured manner, such that the material comprises free surfaces or cavities in a direction parallel to the mirror. This can help make it possible to have a targeted influence on the heat flow and the temperature profiles established therefrom. The deformation layer having a zero crossing-free coefficient of thermal expansion can be provided in or near the neutral axis of the mirror. The neutral axis of the mirror is the region within the mirror which is free of mechanical stresses under pure bending loading. The adaptive mirror can have one or more actuator layers formed as thermal actuator, and can also have one or more actuator layers formed as piezoactuator layer, for example as thin-film piezoactuator layer. The deformation layer can also be designed as a silicon dioxide layer, or as an Al₂O₃ layer or a metal layer (for example aluminum or palladium) or as glass frit.

It can be desirable for the deformation layer to be formed as the elastic mechanical mediator layer, that is to say that the functions of the deformation layer and the mechanical mediator layer can be combined in one layer.

The adaptive mirror can be produced by a method comprising the following steps:
A) providing at least a first main body;
B) applying the actuator layer;
C) applying the elastic mechanical mediator layer to the actuator layer; and
D) coating the elastic mechanical mediator layer with a reflective layer system.

If the actuator layer is formed as a piezoelectric actuator layer, then step B) can comprise applying at least one first electrode, at least one piezoelectric layer and at least one second electrode, wherein the second electrode can be formed in a structured manner. If the actuator layer is formed as a thermal actuator, then step B) can comprise applying a deformation layer having a zero crossing-free coefficient of thermal expansion in particular in an operating range between 20° C. and 60° C. Alternatively, step B) can comprise applying a deformation layer having a coefficient of thermal expansion of zero or approximately zero at a zero crossing temperature (for example in the temperature range of between 5° C. and 15° C.). In this case, the deformation layer can be designed to absorb electromagnetic radiation in the infrared range. Additionally, at least one heating element can be applied between mirror body and deformation layer. Deformation layer and heating element can also be combined and applied in one layer. It is particularly advantageous if the first main body and the second main body are joined in a manner offset with respect to one another. In this regard, the deformation effect of the two main bodies can be combined and the overall effect can thus be better established.

A microlithographic projection exposure apparatus comprising an illumination device and a projection lens includes at least one adaptive mirror according to the disclosure. In this case, the features and configurations described with regard to the adaptive mirror can also be applicable to the microlithographic projection exposure apparatus having the adaptive mirror.

Further features and properties of the present disclosure are described in more detail below on the basis of embodiment variants and with reference to the appended figures. In this respect, all the features described above and below can be implemented individually and in any desired combination. The embodiment variants described below are merely examples which, however, do not limit the subject matter of the disclosure.

### BRIEF DESCRIPTION OF THE DRAWINGS

FIG. 1a shows a schematic illustration of a microlithographic projection exposure apparatus designed for operation in the EUV.

FIG. 1b shows a schematic illustration of a microlithographic projection exposure apparatus designed for operation in the DUV.

FIG. 2 shows a schematic illustration of the construction of a first adaptive mirror.

FIG. 3 shows a schematic illustration of the construction of a second adaptive mirror.

FIG. 4 shows a schematic illustration of the construction of a third adaptive mirror.

FIG. 5 shows a schematic illustration of the construction of a fourth adaptive mirror.

FIG. 6 shows a schematic illustration of the construction of a fifth adaptive mirror.

FIG. 7 shows a schematic illustration of the construction of a sixth adaptive mirror.

FIG. 8 shows a schematic illustration of the construction of a seventh adaptive mirror.

### DETAILED DESCRIPTION

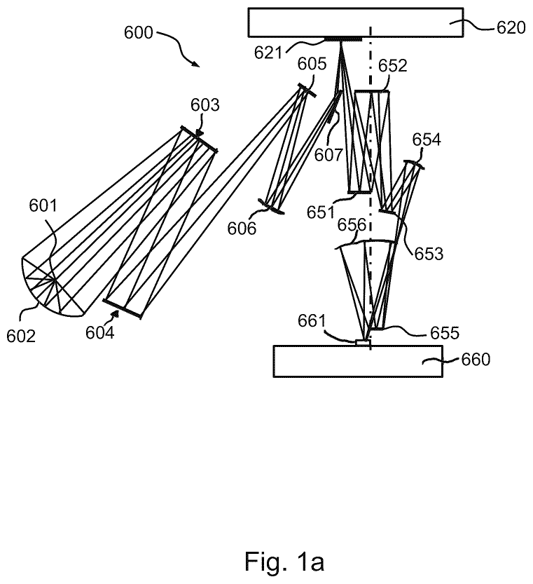

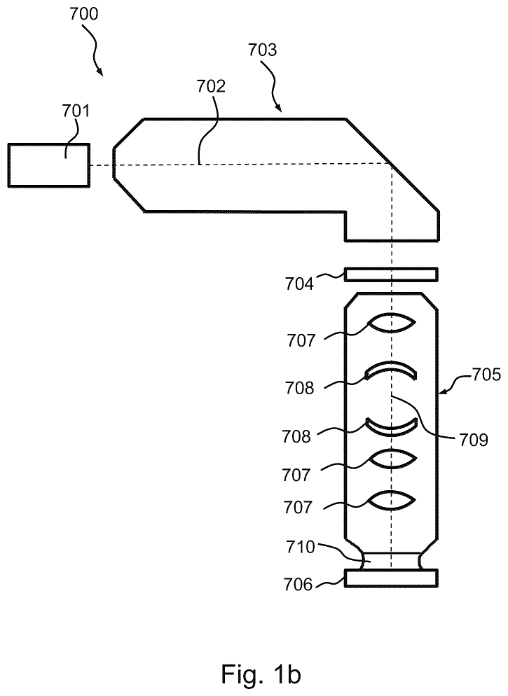

FIG. 1a shows a schematic illustration of an exemplary projection exposure apparatus 600 designed for operation in the EUV, in which the present disclosure is implementable, that is to say in which the actuator 100 according to the disclosure can be used. However, the disclosure can also be used in other nanopositioning systems.

In accordance with FIG. 1a, an illumination device in a projection exposure apparatus 600 designed for EUV comprises a field facet mirror 603 and a pupil facet mirror 604. The light from a light source unit comprising a plasma light source 601 and a collector mirror 602 is directed at the field facet mirror 603. A first telescope mirror 605 and a second telescope mirror 606 are arranged downstream of the pupil facet mirror 604 in the light path. Arranged downstream in the light path is a deflection mirror 607, which directs the radiation incident on it at an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660.

The disclosure can likewise be used in a DUV apparatus, as illustrated in FIG. 1b. A DUV apparatus is set up in principle like the above-described EUV apparatus from FIG. 1a, wherein mirrors and lens elements can be used as optical elements in a DUV apparatus and the light source of a DUV apparatus emits used radiation in a wavelength range of 100 nm to 300 nm.

The DUV lithography apparatus 700 illustrated in FIG. 1b has a DUV light source 701. By way of example, an ArF excimer laser that emits radiation 702 in the DUV range at 193 nm, for example, can be provided as the DUV light source 701. A beam shaping and illumination system 703 guides the DUV radiation 702 onto a photomask 704. The photomask 704 is embodied as a transmissive optical element and can be arranged outside the systems 703. The photomask 704 has a structure which is imaged onto a wafer 706 or the like in a reduced fashion via the projection system 705. The projection system 705 comprises a plurality of lens elements 707 and/or mirrors 708 for imaging the photomask 704 onto the wafer 706. In this case, individual lens elements 707 and/or mirrors 708 of the projection system 705 can be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 may also be provided. In particular, the beam shaping and illumination system 703 of the DUV lithography apparatus 700 comprises a plurality of lens elements 707 and/or mirrors 708. Furthermore, the mirrors are generally curved on their front side for beam shaping purposes. An air gap 710 between the last lens element 707 and the wafer 706 can be replaced by a liquid medium having a refractive index of >1. The liquid medium can be high-purity water, for example. Such a set-up is also referred to as immersion lithography and has an increased photolithographic resolution. The actuators according to the disclosure can be used for the adjustment of the lens elements 707 and or mirrors 708 and/or for the deformation thereof in the DUV lithography apparatus 700, in particular in the projection system 705 thereof.

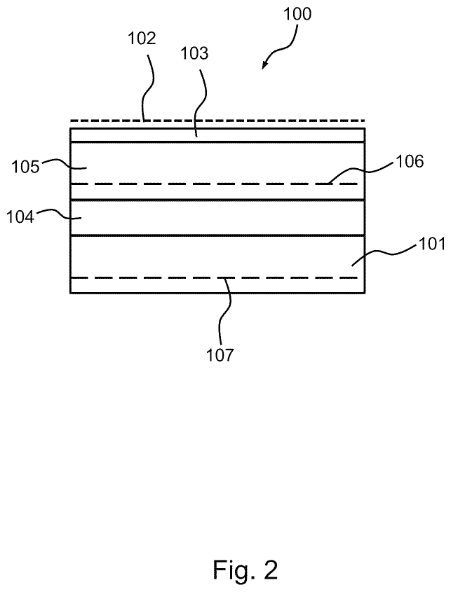

FIG. 2 shows a first adaptive mirror 100 for a microlithographic projection exposure apparatus 600, 700, comprising a mirror substrate 101, comprising an optical effective surface 102 and a reflective layer system 103 for reflecting electromagnetic radiation incident on the optical effective surface 102, and comprising an actuator layer 104 for producing a locally variable deformation of the optical effective surface 102, and comprising a mediator layer 105 arranged between the actuator layer 104 and the reflective layer system 103. The mediator layer 105 is formed as an elastic mechanical mediator layer 105, wherein the thickness of the mechanical mediator layer 105 is between 0.1 mm and 50 mm, such as between 0.1 mm and 20 mm, for example between 0.1 mm and 10 mm, for example between 0.5 mm and 5 mm. Moreover, the modulus of elasticity of the mechanical mediator layer 105 is between 10 GPa and 300 GPa, such as between 50 GPa and 150 GPa, for example between 60 GPa and 80 GPa. The actuator layer 104 is arranged between the mirror substrate 101 and the reflective layer system 103. Dispensing with an electrical mediator layer can help make it possible—if the actuator layer is formed as a piezoactuator or as an electrostrictive actuator—for the control electrodes to be embodied in a manner electrically insulated from one another. This can help make it possible to greatly improve the describability of the optical system and to effectively minimize non-deterministic effects such as creep and hysteresis. Moreover, the possibility can be afforded of using charge control for actuating the piezostrictive layer. This is possible for example even if no electrical connection is present between the actuator layer 104 and the mechanical mediator layer 105. Stray light can be minimized in a targeted manner by the now continuous and smooth progression of the deformation. The mechanical stresses within the actuator layer 104 and high-frequency disturbances of the optical effective surface 102 can be reduced or suppressed by the mechanical mediator layer 105, which can act as a low-pass filter. The elastic mechanical mediator layer 105 additionally constitutes a thermal mass, such that a change in the radiation power absorbed at the optical effective surface 102 can lead to a reduced temporal temperature gradient in comparison with the optical effective surface 102 and a reduced maximum temperature. Heat conduction in the mechanical mediator layer 105 also can result in a lateral heat distribution, such that the temperature profile has only greatly reduced local temperature gradients.

The mechanical mediator layer 105 can be formed in a manner free of piezostrictive and/or magnetostrictive material and can be formed as an electrical nonconductor.

Furthermore, the mechanical mediator layer 105 can be fabricated from the same material as the mirror substrate, such as from fused silica or titanium silicate glass, for example from a titanium silicate glass having a zero crossing temperature, which is then also operated in this temperature range. However, the mechanical mediator layer 105 can also be fabricated from a metal such as aluminum or palladium or from silicon dioxide SiO₂, from aluminum dioxide Al₂O₃ or glass frit.

In order to reduce radiation-induced and thus heat-induced disturbances, provision is made for example for the mechanical mediator layer 105 to have at least one cooling channel 106. The latter is fluid-mechanically connected to a cooling circuit (not illustrated in more specific detail). Alternatively or additionally, the mirror substrate 101 can also have at least one cooling channel 107.

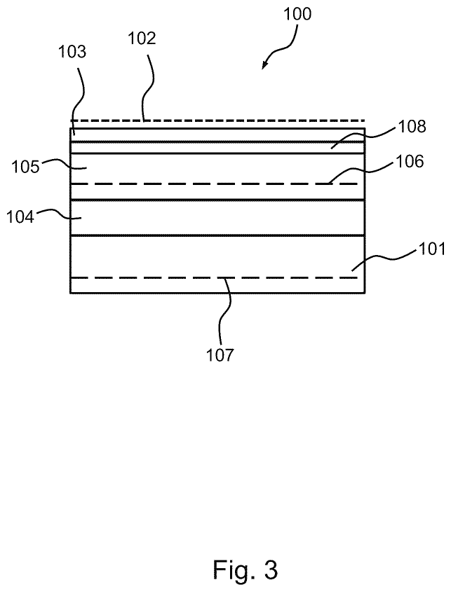

FIG. 3 shows a schematic depiction of the construction of a second adaptive mirror 100, wherein—in comparison with the adaptive mirror 100 described above—a temperature-regulating device 108 is additionally present, too, which is arranged near the optical effective surface in the present case. Alternatively, the temperature-regulating device 108 can also be arranged near or within the actuator layer 104. The temperature-regulating device 108 can be formed as a heating element, such as as a heater or a radiant heater. The heating element can thus be formed for example as a conductor loop or as a piezoelectric layer or as a resistor or from an electrically conductive material or as a coil or as an inductive layer, for example as an inductive metal layer. Furthermore, a temperature sensor (not illustrated in more specific detail) can be present. The temperature sensor can also be arranged on or near the actuator layer 104 or on or near the optical effective surface and can be formed for example as a strain sensor.

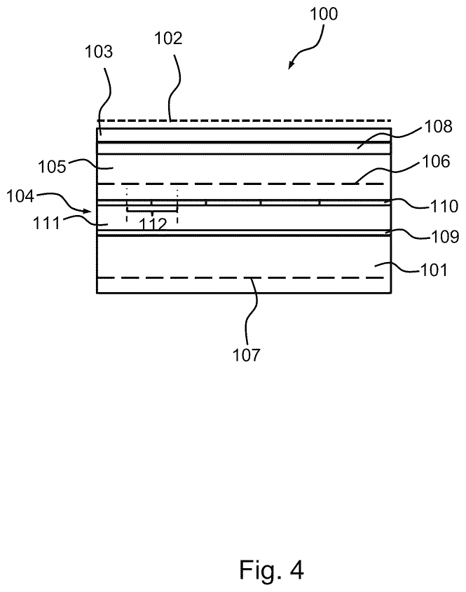

FIG. 4 shows a schematic depiction of the construction of a third adaptive mirror 100, wherein the actuator layer 104 is formed as a piezoelectric actuator layer 111 arranged between a first electrode 109 and a second electrode 110. In the present case, the piezoelectric actuator layer 111 can be formed as a thin-film piezoelectric actuator layer, wherein the thickness of the piezoelectric layer is for example between 1 μm and 1 mm, such as between 1 μm and 100 μm, for example between 1 μm and 10 μm. The ratio of the lateral electrode center-to-center distance 112 to the thickness of the mediator layer 105 can be between 0.1 and 10, such as between 0.2 and 5, for example between 0.5 and 2. In the case that the actuator layer 104 is formed as a piezoelectric actuator layer 111. This means that the piezoelectric actuator layer 111 or an additional piezoelectric actuator layer 111 can also function as a temperature-regulating device 111 and/or as a temperature sensor. The actuator layer 104 can also be formed as a plurality of actuator layers stacked one above another. As a result, the total travel is increased with the layer thickness of the individual actuator layers remaining the same.

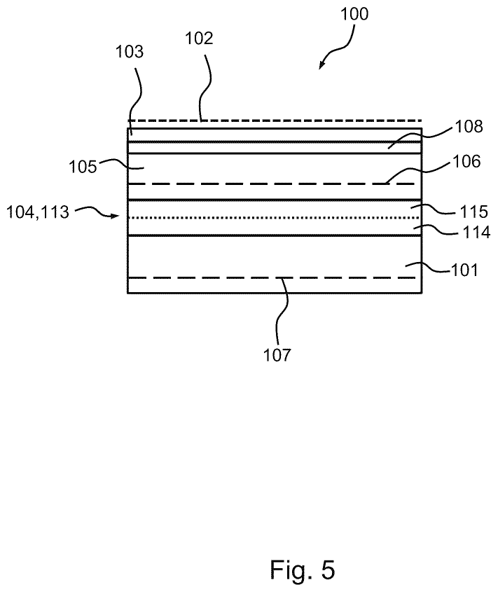

FIG. 5 shows a schematic depiction of the construction of a fourth adaptive mirror 100, wherein the actuator layer 104 is formed as a thermal actuator 113 in the present case.

The thermal actuator 113 comprises a heating element 114 and a deformation layer 115, which is at least thermally, optionally mechanically, connected to the heating element 114 and has a zero crossing-free coefficient of thermal expansion in a used operating temperature range, for example in a used operating temperature range that can lie within the range of between 20° C. and 60° C., such as between 20° C. and 40° C. The heating element 114 and the deformation layer 115 can be formed as two separate layers, which are joined together or which are coated one on the other, or else the heating element 114 can be integrated into the deformation layer 115. The heating element 114 can be formed as a conductor loop or as a piezoelectric layer or as a resistor or from an electrically conductive material or as a coil or as an inductive layer, for example as an inductive metal layer. By virtue of the deformation layer having a coefficient of thermal expansion (CTE) not equal to zero, the deformation layer 115 can expand via the heat input through the heating element 114 and thus locally can cause the deformation of the reflective layer system 103 and thus a wavefront change. In FIG. 5, the deformation layer 115 is arranged between the heating element 114 and the mechanical mediator layer 105. However, the deformation layer 115 can also be arranged between the mirror substrate 101 and the heating element 114. The deformation layer 115 can be formed from the same material as the mirror substrate 101. Alternatively—and not shown—the thermal actuator 113 can also be formed exclusively from a deformation layer 115, optionally designed to absorb electromagnetic radiation in the infrared wavelength range. In this embodiment, the heat input into the deformation layer 115 takes place as a result of absorption of the electromagnetic radiation in the infrared wavelength range, whereby a deformation of the deformation layer 115 at least in portions is attained.

Alternatively, the deformation layer 115 can also have a coefficient of thermal expansion of zero or approximately zero at a zero crossing temperature (ZCT) and the heating element 114 can be designed to change the temperature in the deformation layer 115 to a temperature not equal to the zero crossing temperature, in order to induce an at least regional layer thickness change of the deformation layer 115. In this case, the deformation layer 115 can be formed as mirror material and optionally from the same material as the mirror substrate 101. Operating the deformation layer at a temperature different than its zero crossing temperature causes a temperature-induced deformation of the deformation layer 115. Alternatively—and not shown—the thermal actuator 113 can also be formed exclusively from a deformation layer 115, optionally designed to absorb electromagnetic radiation in the infrared wavelength range. In this embodiment, the heat input into the deformation layer 115 takes place as a result of absorption of the electromagnetic radiation in the infrared wavelength range, whereby a deformation of the deformation layer 115 at least in portions is attained.

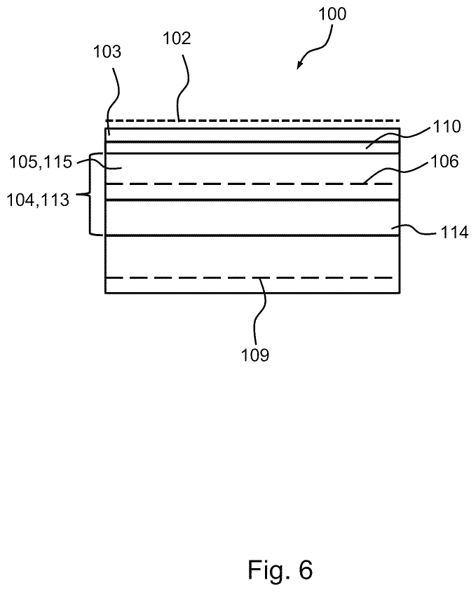

FIG. 6 shows an adaptive mirror 100 in which the elastic mechanical mediator layer 105 is formed as the deformation layer 115. This can help make it possible to attain a simplified layer construction and to combine different functions within the adaptive mirror 100.

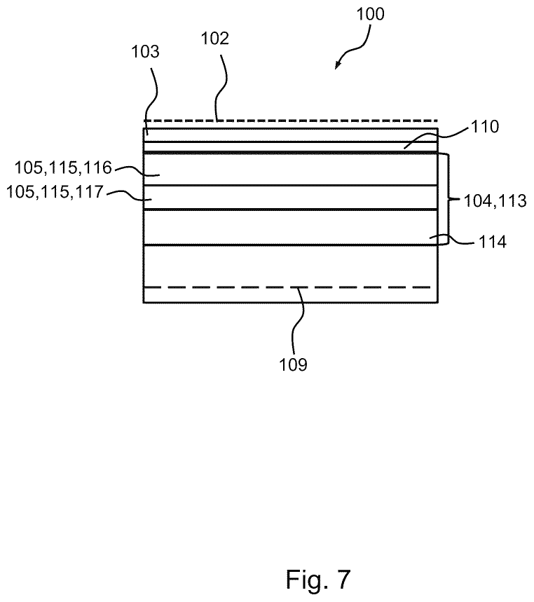

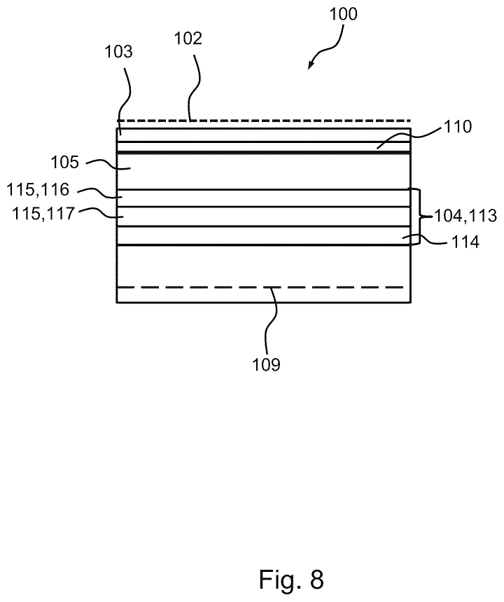

In accordance with the exemplary embodiment according to FIG. 7, the deformation layer 115 can have a first region 116 or a first layer, in which the coefficient of thermal expansion is approximately zero at a first zero crossing temperature, and a second region 117 or a second layer, in which the coefficient of thermal expansion is zero or approximately zero at a second zero crossing temperature different than the first zero crossing temperature. For example, the regions can be embodied as layers. The different regions or layers with mutually different zero crossing temperatures can help enable a spatial separation of desired, heat-induced deformation of the actuator layer and unwanted radiation-induced deformation. As shown in FIG. 7, the first zero crossing temperature at the first region, near the optical effective surface 102 and near the reflective layer system 103, can be chosen in such a way that the temperature range of the heating induced by the electromagnetic radiation is exactly in the range of the first zero crossing temperature, such that (unwanted) thermal expansion and thus deformation are prevented. Conversely, the second region 117 or the second layer 117 can have a second zero crossing temperature, which is not equal to the first zero crossing temperature and is spaced apart from the latter, such that the heating element 114 heats the second region 117 to a temperature range different than the first zero crossing temperature and in accordance with the second zero crossing temperature, in order to cause a deformation of the deformation layer 115 in a targeted manner. FIG. 7 illustrates the case in which the mechanical mediator layer 105 is formed as the deformation layer 115. By contrast, the exemplary embodiment according to FIG. 8 shows an adaptive mirror 100 analogous to the exemplary embodiment according to FIG. 7, in which the deformation layer 115 and the mechanical mediator layer 105 are formed as separate layers.

### LIST OF REFERENCE SIGNS

100 Adaptive mirror
101 Mirror substrate
102 Optical effective surface
103 Reflective layer system
104 Actuator layer
105 Elastic mechanical mediator layer
106 Cooling channel (mechanical mediator layer)
107 Cooling channel (mirror substrate)
108 Temperature-regulating device
109 First electrode
110 Second electrode (control electrodes)
111 Piezoelectric actuator layer
112 Lateral electrode center-to-center distance
113 Thermal actuator
114 Heating element
115 Deformation layer
116 First region (deformation layer)
117 Second region (deformation layer)
600 Projection exposure apparatus
601 Plasma light source
602 Collector mirror
603 Field facet mirror
604 Pupil facet mirror
605 First telescope mirror
606 Second telescope mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

What is claimed is:

1. A mirror having an optical effective surface, the mirror comprising:
a mirror substrate;
a reflective layer system configured to reflect electromagnetic radiation incident on the optical effective surface;
an actuator layer configured to produce a locally variable deformation of the optical effective surface;
a mediator layer between the actuator layer the reflective layer system;
a first electrode; and
a second electrode,
wherein:
the mediator layer has a thickness of between 0.1 millimeter (mm) and 50 mm;
the mediator layer has a modulus of elasticity of between 10 Gigpascals (GPa) and 300 GPa; and
the actuator layer comprises an electrostrictive layer or a piezoelectric actuator layer; and
the actuator layer is between the first and second electrodes.

2. The mirror of claim 1, wherein the mediator layer is free of at least one member selected from the group consisting of a piezostrictive material, a magnetostrictive material and an electrostrictive material.

3. The mirror of claim 1, wherein the mediator layer is free of at least two members selected from the group consisting of a piezostrictive material, a magnetostrictive material and an electrostrictive material.

4. The mirror of claim 1, wherein the mediator layer is free of a piezostrictive material, a magnetostrictive material and an electrostrictive material.

5. The mirror of claim 1, wherein the mediator layer comprises an electrical nonconductor.

6. The mirror of claim 1, wherein the mediator layer and the mirror substrate comprise the same material.

7. The mirror of claim 1, wherein the mediator layer comprises a cooling channel.

8. The mirror of claim 1, wherein the mirror substrate comprises a cooling channel.

9. The mirror of claim 1, further comprising a temperature-regulating device, wherein the temperature-regulating device is on the optical effective surface, near the optical effective surface, on the actuator layer, and/or near the actuator layer.

10. The mirror of claim 9, wherein the temperature-regulating device comprises a heating element.

11. The mirror of claim 1, wherein further comprising a temperature sensor, wherein the temperature sensor is on the actuator layer, near the actuator layer, within the actuator layer, on the optical effective surface, and/or near the optical effective surface.

12. The mirror of claim 1, wherein the actuator layer has thickness of between 0.1 microns (μm) and 10 μm.

13. The mirror of claim 1, wherein a ratio of a lateral electrode center-to-center distance to a thickness of the mediator layer is between 0.1 and 10.

14. The mirror of claim 1, wherein the actuator layer comprises a multilayer system.

15. The mirror of claim 1, further comprising an electrical mediator layer.

16. The mirror of claim 1, wherein:
the mediator layer is free of at least one member selected from the group consisting of a piezostrictive material, a magnetostrictive material and an electrostrictive material; and
the mediator layer comprises an electrical nonconductor.

17. The mirror of claim 1, wherein:
the mediator layer is free of at least one member selected from the group consisting of a piezostrictive material, a magnetostrictive material and an electrostrictive material; and
the mediator layer and the mirror substrate comprise the same material.

18. The mirror of claim 1, wherein:
the mediator layer is free of at least one member selected from the group consisting of a piezostrictive material, a magnetostrictive material and an electrostrictive material; and
the mediator layer comprises a cooling channel, and/or the substrate comprises a cooling channel.

19. An apparatus, comprising:
an illumination device comprising a mirror according to claim 1; and
a projection lens,
wherein the apparatus is a microlithographic projection exposure apparatus.

20. An apparatus, comprising:
an illumination device; and
a projection lens comprising a mirror according to claim 1,
wherein the apparatus is a microlithographic projection exposure apparatus.
